(19) United States
(12) Patent Application Publication
(10) Pub. No.: US 2013/0197835 A1
(43) Pub. Date: Aug. 1, 2013

(54) CIRCUIT BREAKER METERING SYSTEM

(71) Applicants: Hilmir Ingi Jonsson, Grindavik (IS); Halldor Axelsson, Hafnarfjordur (IS); Bjarni Malmquist Jonsson, Reykjavik (IS); Ragnar Einarsson, Reykjavik (IS); Jon Thor Olafsson, Gardabaer (IS)

(72) Inventors: Hilmir Ingi Jonsson, Grindavik (IS); Halldor Axelsson, Hafnarfjordur (IS); Bjarni Malmquist Jonsson, Reykjavik (IS); Ragnar Einarsson, Reykjavik (IS); Jon Thor Olafsson, Gardabaer (IS)

(73) Assignee: RE-MAKE ELECTRIC EHF, Hafnarfjordur (IS)

(21) Appl. No.: 13/697,330

(22) PCT Filed: May 10, 2011
(86) PCT No.: PCT/IS2011/050007

§ 371 Date: Mar. 28, 2013

(30) Foreign Application Priority Data
May 10, 2010 (IS) 8898

(51) Int. Cl. G01R 21/00

(52) U.S. Cl. CPC G01R 21/001
USPC 702/62

(57) ABSTRACT

A system of using electrical detection and reporting devices in conjunction with existing electrical protection devices by an electrical installation, wherein the said measuring devices are used by existing circuit breakers and terminal blocks to measure and identify electrical load and residual current in said electrical installation. The system measures residual current, current and voltage and displays information on said measurements by LEDs wherein the system consists of using a dedicated CPU for collecting, analysing and transmitting the data of the system through wireless and Ethernet/internet connections.

### FIELD OF THE INVENTION

The present invention relates to a system of measuring devices in conjunction to electro protection devices and centralized processing units for monitoring and identifying electrical parameters and load by an electrical installation in a building.

### BACKGROUND OF THE INVENTION

Global electricity demand is constantly rising creating an overload and high peak period issues for the electricity supply distribution network. To respond to this issue a Smart Grid is being evolved to better manage peak loads of the distribution network and feed in renewable energy. The Smart Grid is an evolution for helping utilities to ensure the reliable, cost-effective and environmentally-friendly management and distribution of energy. The Smart Grid is mainly intended for the benefits of the utilities but not the consumers as it only offers the consumer a potential way to manage their electrical consumption by provided tariff information.

Although Smart Grid technologies can provide the consumer with a building's total electrical consumption and electrical load along with tariff data by various approaches none can analyse and identify where said total information is derived from.

In typical buildings circuit breakers are used to control and manage circuit branch electricity flow throughout the building. Circuit breakers are known in the art to hold and break electrical feed from the electrical supply to connected electrical outlets or appliances in a building. Also, circuit breakers are known to have integrated electrical load indication means for displaying electrical statuses and parameters to consumers. Such circuit breakers use electronic current measurement means, by resistor sensors such as Hall Effect sensors, in which a processor is included to receive and process the measurements. The processor is known in the art to comprise and provide indication means located on the front face of the circuit breaker for easy access to the data in which the data can be indicated by display of a LED or LEDs and also by LCD monitor.

Although circuit breakers with integrated electronic measurement means and indication means referenced above offer accessible electrical measurement factors they can be considered to risk the circuit protection function of circuit breakers by implementing said integrated electronic measuring means to a circuit breaker. Also, this requires complete reconstruction of circuit breakers to replace existing circuit breakers by electrical installations in buildings.

Ground terminal blocks are known in the art to be used for connecting ground/earth connections from inside electrical panels to external electrical applications. Ground terminal blocks can be a part of a multi terminal block in which comprises connection to pole, neutral and ground connection to electrical applications. Residual current circuit breakers (RCCD) are connected to ground terminal blocks at a communal connection point for detecting residual current from each ground terminal block, wherein each ground terminal block represents each circuit branch of an electrical installation in a building. The RCCD trips by detecting residual current and therefore stops electrical feed to circuit breakers connected to the said RCCD to protect humans and appliances from electrical shock.

Although ground terminal blocks are used to link RCCDs with residual current and RCCDs trip when connected with residual current for protection purposes neither can identify from which circuit branch the residual current originated from.

### SUMMARY OF THE INVENTION

It is an object of the present invention is to provide an improved system of utilizing various types of circuit breakers, terminal blocks and CPUs by arrangements and methods for detecting and reporting electrical measurements in an electrical system. Furthermore, it is an objective is to advance electrical installation systems by providing data on residual current load and residual current incidents by an electrical installation application. The device and system of the present invention can detect and report electrical load from individual electrical protection devices such as circuit breakers and terminal blocks. Through CPU means (such as an industrial computer) the information on load in the system can be reported to the user or sent to switching devices to turn on or off electricity to certain electrical devices or areas within the electrical system.

The present invention provides effortless arrangement to advance an existing electrical installation of a building into an informative micro smart grid of the building. The micro smart grid is used by the consumer to monitor and identify detailed electrical data for making energy efficient improvements. This is achieved by providing accessible data on electrical measurements by a electrical detection and reporting device for electrical protection devices together with data communication through a linking unit from the electrical detection and reporting device to a CPU in which is able to display the data by internal or external monitors or computers.

The present invention provides a system and devices for collecting measurement data from electro components in existing electrical installation of a building by each circuit branch through installed terminal blocks, circuit breakers, supply mains and Smart Meters to make the most of existing installation without losing comfort or creating reconstruction of the installation for the consumer.

The present invention provides a Micro Smart Grid to enhance the Smart Grid to consumer level. This provides a system to present to the consumer the details from the electrical network of their buildings own electrical installation and operation. The present invention consists of using a separate electrical detection and reporting device in combination with electrical protection devices such as circuit breakers, residual current circuit breakers and ground terminal blocks for monitoring separate circuit branches, wherein measurement data is transmitted from the electrical detection and reporting device to a CPU for collection and communication.

In a first aspect of the present invention an electrical detection and reporting device is provided to be used in combination with electrical protection devices, the electrical detection and reporting device comprising a housing, an electrical detection unit, a printed circuit board, and an output means. The device is characterised in that the electrical detection and reporting is connected to the electrical protection device and to a CPU and further in that the electrical detection and reporting detects and communicates electrical load from electrical protection devices to the CPU. The CPU monitors the load and delivers data or signals to a user about the electrical load in each electrical protection device. When the electrical protection devices are circuit breakers, the electrical detection unit is a current transformer, the current transformer produces a reduced current proportional to the current flowing through the wire or conductor. When the electrical protection devices are terminal blocks, such as pole-, neutral- or ground terminal blocks, a reporting unit delivers signal of ground fault to the CPU.

In a second aspect of the present invention a system for monitoring and displaying electrical load in an electrical installation system is provide. The system comprises at least one electrical protection device, at least one electrical detection and reporting device according to the present invention, and a CPU unit. The system is characterised in that the at least one electrical detection and reporting device is connected to the electrical protection device and to the CPU. Furthermore, the system is characterised in that the electrical detection and reporting communicates load from electrical protection devices to the CPU and in that the CPU monitors and delivers signals to a user about the load in each electrical protection device.

### DESCRIPTION OF THE INVENTION

The following embodiments relate to both the device and the system of the present invention.

In an embodiment of the present invention the CPU is an integrated part of the device and contained within the housing, reporting information by wired or wireless connections.

In another embodiment of the present invention the CPU is an external part of the device and connected to the electrical detection and reporting information by wired or wireless connections.

In an embodiment of the present invention the electrical detection and reporting device further comprises a signalling means. The signalling means can be an LDC, at least one LED or an array of LEDs, where the at least one LED is on the front face of the housing to be accessible on the front face of a circuit breaker. Furthermore, the signalling means can also be an acoustic buzzer alone or in combination with LED(s) or an LDC display.

In an embodiment of the present invention the CPU is a part of a Residual Current Circuit Breaker.

In an embodiment of the present invention the CPU measures voltage through power supply inputs.

In an embodiment of the present invention the CPU reads data from Smart Meters.

In an embodiment of the present invention the CPU transmits data through wired or wireless connection to an internet modem. This provides a reporting platform to deliver information relating to electrical use or load to a user. This can be through a direct link to a remote server or through e-mail or (sms) text messages. This is advantageous as although the electrical detection and reporting device has display and/or acoustic signalling means, these do not function when no person is in close proximity to the electrical system. The device and system of the present invention also provide options for electricity providers in demand response systems for controlling the amount of electricity to the user through information from Smart Meters delivered to the CPU.

The electrical detection and reporting device comprises an electronic circuit to measure current and residual current by aforementioned devices. The electrical detection and reporting device has input/output means wherein the input/output means could be made able for one or all of: computing with CPU, operating the circuit and powering the circuit.

The electronic circuit of the electrical detection and reporting device could comprise at least one LED made accessible for indicating an electrical state in which the state could be a parameter of a pre-determined value of electrical load, overload situation or a near-trip situation, furthermore the circuit could comprise a number of LEDs to indicate various electrical current levels or types of data levels. The data could also in addition or as an alternative to LEDs be presented by a LCD monitor.

The electrical detection and reporting device of the invention can be arranged to be used as an external accessory or an independent internal supplement to electrical protection devices such as a Ground Terminal Block, Miniature Circuit Breaker (MCB), Residual Current Circuit Breaker (RCCB) or a Molded Case Circuit Breaker (MCCB) wherein the device is separate from all the said circuit breakers mechanism. To prevent affecting the protection function of said circuit breakers the electrical detection and reporting device could be energized from the CPU by the input means of the electrical detection and reporting device or as an alternative the electrical detection and reporting device could be self-powered by the reduced current from a current transformer of the electrical detection and reporting device. The electrical detection and reporting device of the invention comprises at least one indication LED or an LCD to be accessible on the front face of said circuit breakers and could transmit data to a CPU able to compute and transmit the data by wired connections or wireless signals for load status in real time.

The present invention further provides a linking unit to be used in combination with the electrical detection and reporting device and a CPU.

In an embodiment of the present invention the linking unit is a Printed Circuit Board (PCB) strip as a busbar. The PCB busbar contains integrated connections to link each electrical detection and reporting device to a CPU.

In another embodiment of the present invention the linking unit is a component containing a PCB strip comprising at least one electrical detection and reporting device and a CPU at the end of the stip. The linking unit as a PCB busbar could be arranged to contain a buzzer in which is activated when one or more measurements rise above a set electrical parameter by the connected electrical detection and reporting device.

In an embodiment of the present invention the linking unit as a connection busbar between the electrical detection and reporting device and CPU is arranged to have at least one connection element to be connected to the input/output means of the electrical detection and reporting device, where the linking unit comprises as many connection elements as to match the number of components to be linked to. The connection element is locked in place by lock-in means of the input/output means of the electrical detection and reporting device for secure and reliable connections amid.

In another embodiment of the present invention the link unit is a wire or cable arrangement from the electrical detection and reporting device to a CPU or as an additional connection element to be linked to a CPU.

In an embodiment of the present invention the processed data from the CPU is sent via USB, Meter Bus (M-Bus), Ethernet or wireless communication to external monitors or computers and Smart Meters, furthermore the data could be sent partially or wholly through a Short Message Service of the said CPU.

In a specific embodiment of the present invention the electrical detection and reporting device and the CPU comprise an acoustic buzzer. The acoustic buzzer can be arranged to indicate levels of a predetermined value or faults by sounding alarm signals.

In an embodiment of the present invention the CPU is arranged to be in DIN rail mounted housing as a part of or as extension of the electrical detection and reporting device or linking unit. The housing of the CPU can be arranged to comprise an LCD monitor and or at least one LED for operation and data indication and display purposes along with communication ports for USB, Meter Bus (M-Bus), Ethernet or wireless communication to external monitors or computers and Smart Meters.

In an embodiment of the present invention the CPU's DIN rail mounted housing is a Residual Current Circuit Breaker (RCCD).

In an embodiment of the present invention the CPU stores the data from each electrical detection and reporting device and broadcasts the data through proprietary software by internet connection. The CPU is also read data from Smart Meters to identify total electrical consumption and can measure current and voltage from the electrical supply mains. The data is made accessible to the consumer by software and displayed on a website, where the consumer can customize his data display and notifications on each electrical aspect of his installation.

In an embodiment of the present invention the CPU is arranged to be a joint part of the electrical detection and reporting device, where the electrical detection and reporting device connects to at least one circuit breaker or ground terminal block. The CPU can furthermore be a part of a separate collective measuring unit consisting measurement means for at least one circuit branch analysis wherein the unit is connected directly to or as an alternative separately connected to circuit breakers and ground terminal blocks. In such an embodiment the measuring unit is used as an accessory to measure current and residual current by circuit breakers and ground terminal blocks and transmit data from said measuring unit to separate devices. The measuring unit can be arranged to be powered by external power supply for the CPU and could be arranged without indication means.

The electrical detection and reporting device for ground terminal blocks has a residual current sensor wherein a LED is lighted to indicate residual current incidents. In such an embodiment, the ground terminal block can be a part of a multi connection terminal block to connect phase, neutral and ground to electrical applications, where the ground connection of said multi terminal block comprises the electrical detection and reporting device of the invention.

The CPU can also be arranged to comprise output means for controlling electrical switching devices in and to response to electrical parameters and time factors of the information from the connected electrical detection and reporting devices of the system.

The CPU can be arranged to provide memory, detection and or measurement function for any or all of: line current, line voltage, over-current, over-voltage, under-voltage, temperature, power measurement, power factor and residual current.

Advantageously, the system of using the invention's electrical detection and reporting devices for various types of circuit breakers, ground terminal blocks, CPUs and a linking unit presents an arrangement for measuring electricity in a building without needing to reconstruct the existing electrical installation. Another advantage is to identify electrical information on each connected circuit branch of an installation. These advantages are found by creating a electrical detection and reporting device in which connects to existing electrical protection components to monitor and transmit electrical information from existing installation.

A specific objective with the invention is to provide a sustainable and improved arrangement to make measurements accessible for the consumer simply by looking into their existing electrical distribution panels. The consumer can identify electrical information and load statuses by each circuit branch along with receiving data from each circuit branch to a mobile phone, monitor and or computer. The objective is reached by making electrical information accessible by the electrical detection and reporting device's indication means on the front face of a circuit breaker and by linking the electrical detection and reporting device to a CPU for data analysis and broadcasting.

The present invention is characterized by using a electrical detection and reporting device as a module to be fastened or integrated to various types of circuit breakers as a separate unit apart from the protection and functioning mechanism of circuit breakers. It is also characterized by using a linking unit as a busbar to connect said electrical detection and reporting devices to a CPU in which interacts with said linking unit to receive measurements from the electrical detection and reporting devices. The present invention is furthermore characterized for providing indication means by connected circuit breakers on the front face of the circuit breakers for easy and instant read-out.

The system of the invention is still also characterized by using ground terminal blocks with residual current sensor means to identify residual current incidents. The ground terminal blocks are characterized by a LED in which identifies from which circuit branch a residual current was detected.

### BRIEF DESCRIPTION OF DRAWINGS

FIG. 1 shows the electrical detection and reporting devices placed on circuit breakers providing indication LEDs to the front face of the circuit breakers wherein the linking unit provides data by conductors to the CPU.

FIG. 2 shows the preferred setup of the installation of the system of the invention to existing electrical installation in an electrical panel.

FIG. 3 shows the electrical detection and reporting device and a compact module for conjunction with circuit breakers and terminal blocks.

### DESCRIPTION OF THE PREFERRED EMBODIMENTS

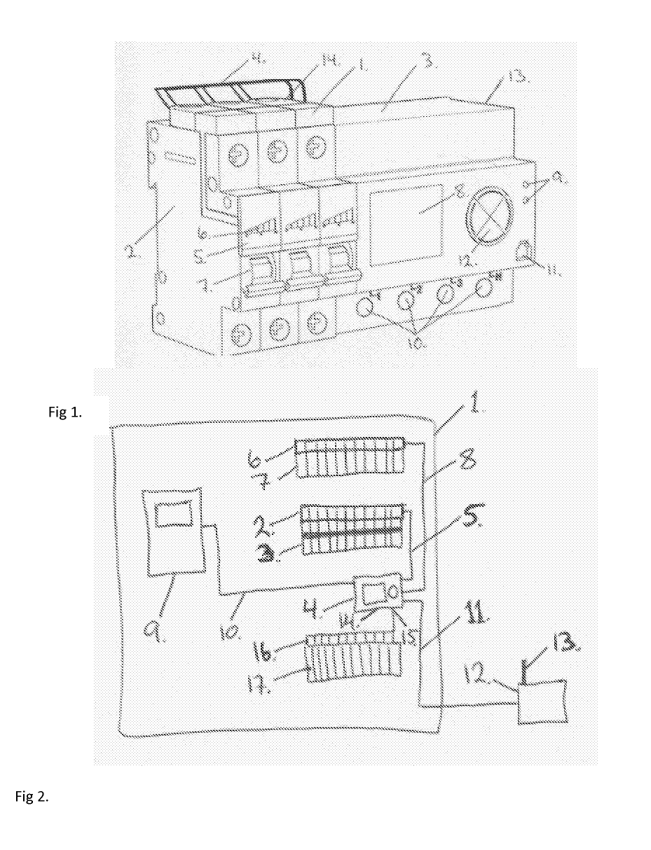

In FIG. 1 a drawing of the electrical detection and reporting devices (1) as separate modules mounted on conventional miniature circuit breakers (MCBs) (2) along with the CPU (3) by DIN rail housing module (13). The CPU (3) is connected to the said electrical detection and reporting devices (1) of the said circuit breakers (2) wherein the connection from the electrical detection and reporting devices (1) to the CPU (3) is obtained through collective wirings (4) in which can be a printed board circuit strip (not shown). The electrical detection and reporting device (1) is powered by the reduced current from the current transformer (14) in which also provides the current measurements to the CPU (3) for analysis. The electrical detection and reporting device (1) has a electrical detection and reporting device module (5) in which covers the front face of the MCB (2) to present accessible indication of electrical current flowing through the said MCB (2) wherein the indications are made accessible by an array of LEDs (6). The MCB (2) comprises a switch (7) for controlling the protection function of the MCB (2) in which is separate from and unaffected by the electrical detection and reporting device (1) along with the electrical detection and reporting device module (5) on the front face of the MCB (2). The CPU (3) comprises an LCD screen (8) to display the electrical information from the analysis of measurements from the electrical detection and reporting devices (1) and has functioning buttons (12) to choose information readings from. The CPU (3) comprises power inputs (10) to measure the voltage of the connected electrical system along with powering the CPU (3) by said inputs (10). The CPU comprises a connection port (11) in which can be a USB port to connect and make transmission of data read-out able to computers.

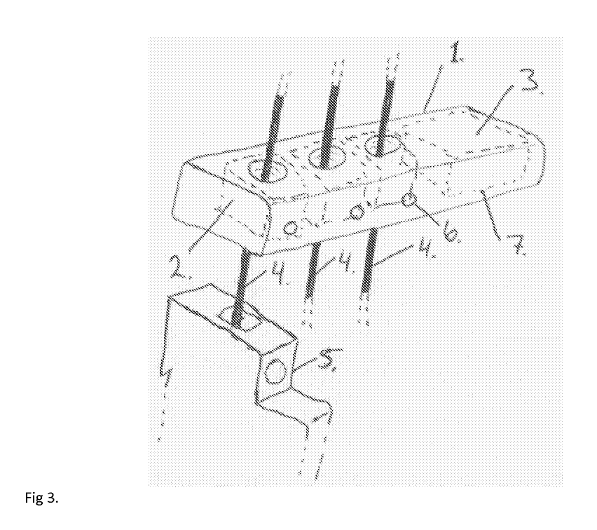

In FIG. 2 a block diagram of the system according to the present invention in an electrical panel (1) wherein the CPU (4) is a collective central station for collecting, analysing and transmitting data from the system. The system is based on the electrical detection and reporting devices (2) connected to miniature circuit breakers (3) for measuring current from individual circuit branches wherein the CPU (4) collects measurements by wireless or wired connections (5) from the electrical detection and reporting devices (2). The CPU (4) can also collect measurements from electrical detection and reporting devices (6) connected to ground terminal blocks (7) measuring residual current from individual circuit branches by wireless or wired connections (8). The CPU (4) can furthermore connect to a Smart Meter (9) by counting the flashing LED (not shown) on the Smart Meter (9) by infrared connection or by communicating with the Smart Meter (9) by communication cable (10). The CPU (4) can transmit data locally by USB port (not shown) or through the internet by connection to a modem (12) by wireless or wired connection (11). The modem (12) can further transmit the data through wireless signals by the modems (12) antenna (13). The CPU (4) also comprises inputs (14) for voltage measurements in which are also used to energize the CPU (4). The system can also be arranged to have output means (15) by the CPU (4) for controlling trip units or switching devices (17) by a connection cable (16). The CPU (4) can control power supply to electrical applications (not shown) by said switching devices (17) of an electrical installation in electrical panels (1).

In FIG. 3 a drawing of a specific embodiment of the electrical detection and reporting device (1) of the present invention is presented to comprise the CPU (3) in a compact module (1). The module comprises current transformers (2) for individual measurements of circuit breakers (5) along with a CPU (3) in which can transmit data through wireless or wired connections to other computers (not shown) or the alike. The CPU (3) collects measurements from each current transformer (2) and can also receive measurements from other electrical detection and reporting devices (1) for storing and transmitting collective data from a communal transmission point to external computers or the alike. The compact electrical detection and reporting device module (1) can be connected directly to circuit breakers (5) as an accessory supplement to circuit breakers (5) or used in combination with circuit breakers (5) by being placed above circuit breakers (5) by an electrical installation in an electrical panel (1). This embodiment (1) can also be arranged to measure residual current from ground conductors (not shown) or ground terminal blocks (not shown). This embodiment (1) could comprise indication LEDs (6) for indicating electrical parameters of the system or by each circuit breaker (5). The electrical detection and reporting device (1) can be powered by the reduced current from the current transformers (2) or be connected to power supply by power supply inputs (7).

1. An electrical detection and reporting device to be used in combination with electrical protection devices, the electrical detection and reporting device comprising:
a housing,
an electrical detection unit, and
an input/output means,
CHARACTERIZED IN THAT,
the electrical detection and reporting device is electrically connectable to the electrical protection device,
the electrical detection and reporting device is electrically connected to a CPU via a linking unit,
the electrical detection and reporting device is adapted to be energized from the CPU by the input means of the electrical detection and reporting device,
the electrical detection and reporting device comprises an electronic circuit to measure current and residual current by said at least one electrical protection device,
and the electrical detection and reporting device communicates electrical load from at least one electrical protection device to the CPU via said linking unit, the CPU adapted to monitor the load and delivers data to a user on the electrical load in the at least one electrical protection device.

2. The electrical detection and reporting device according to claim 1, wherein the CPU is an integrated part of the electrical detection and reporting device and contained within the housing.

3. The electrical detection and reporting device according to claim 1, wherein the CPU is an external part of the electrical detection and reporting device and electrically connectable to the electrical detection unit.

4. The electrical detection and reporting device according to claim 1, wherein the electrical detection and reporting device further comprises a signalling means.

5. The electrical detection and reporting device according to claim 4, wherein the signalling means is at least one LED.

6. The electrical detection and reporting device according to claim 4, wherein the signalling means is an acoustic buzzer.

7. The electrical detection and reporting device according to claim 4, wherein the signalling means is an LCD.

8. The electrical detection and reporting device according to claim 1, wherein the CPU is a part of a Residual Current Circuit Breaker.

9. The electrical detection and reporting device according to claim 1, wherein the CPU measures voltage through power supply inputs of the electrical detection and reporting device.

10. The electrical detection and reporting device according to claim 1, wherein the CPU reads and communicates data from Smart Meters.

11. The electrical detection and reporting device according to claim 1, wherein the CPU transmits data through wired or wireless connection to an internet modem.

12. The electrical detection and reporting device according to claim 1, wherein the electrical protection devices are circuit breakers.

13. The electrical detection and reporting device according to claim 12, wherein the electrical detection unit is a current transformer, the current transformer produces a reduced current proportional to the current flowing through the wire or conductor.

14. The electrical detection and reporting device according to claim 1, wherein the electrical protection devices are terminal blocks.

15. The electrical detection and reporting device according to claim 1, wherein the CPU has output means for controlling electronic switching devices.

16. The electrical detection and reporting device according to claim 1, wherein the linking unit is one of a printed circuit board strip, a printed circuit board busbar, or a DIN rail mounted housing.

17. The electrical detection and reporting device according to claim 1, wherein the linking unit is a component containing a printed circuit board strip.

18. A system for monitoring and displaying electrical load in an electrical system, the system comprising:
at least one electrical protection device,
at least one electrical detection and reporting device according to any of the preceding claims, and
CPU.

19. The system according to claim 18, wherein the CPU reads data from Smart Meters.

20. The system according to claim 18, wherein the CPU transmits data through wired or wireless connection to an internet modem.

21. The system according to claim 18, wherein the electrical protection devices (2) are circuit breakers.

22. The system according to claim 21, wherein the electrical detection unit is a current transformer, the current transformer produces a reduced current proportional to the current flowing through the wire or conductor.

23. The system according to claim 18, wherein the electrical protection devices are terminal blocks.

24. The system according to claim 18, wherein the CPU has output means for controlling electronic switching devices.
